(19) United States
(12) Patent Application Publication
(10) Pub. No.: US 2025/0392145 A1
(43) Pub. Date: Dec. 25, 2025

(54) ELECTRONIC DEVICE INCLUDING CHARGING CRADLE AND METHOD OF OPERATING SAME

(71) Applicant: Samsung Electronics Co., Ltd., Suwon-si (KR)

(72) Inventors: Seungho LEE, Suwon-si (KR); Jaewon Choi, Suwon-si (KR)

(73) Assignee: Samsung Electronics Co., Ltd., Suwon-si (KR)

(21) Appl. No.: 19/256,960

(22) Filed: Jul. 1, 2025

Related U.S. Application Data
(63) Continuation of application No. PCT/KR2025/008325, filed on Jun. 17, 2025.

(30) Foreign Application Priority Data
Jun. 25, 2024 (KR) 10-2024-0083008
Sep. 3, 2024 (KR) 10-2024-0119092

(51) Int. Cl. H02J 7/00

(52) U.S. Cl. CPC H02J 7/0042; H02J 7/0047; H02J 7/00714

(57) ABSTRACT

An electronic device may include: connector pins including a first pin and a second pin configured to transmit power or a communication signal; a power supply; a current detection sensor configured to detect charging current transmitted through the first pin; at least one processor including processing circuitry; a switch configured to enable one of the power supply and the at least one processor to be connected to the first pin; and memory configured to store instructions that, when executed by the at least one processor, cause the electronic device to: based on connector terminals of a wearable device being connected to the connector pins, transmit the power to the wearable device through a first path connected to the first pin and the power supply; and communicate data with the wearable device through a second path.

### CROSS-REFERENCE TO RELATED APPLICATIONS

This application is a continuation of International Application No. PCT/KR2025/008325 designating the United States, filed on Jun. 17, 2025, in the Korean Intellectual Property Receiving Office and claiming priority to Korean Patent Application No. 10-2024-0083008, filed on Jul. 25, 2024, in the Korean Intellectual Property Office, and Korean Patent Application No. 10-2024-0119092, filed on Sep. 3, 2024, in the Korean Intellectual Property Office, the disclosures of which are incorporated by reference herein in their entireties.

### BACKGROUND

### 1. Field

The disclosure relates to an electronic device including a charging cradle, and more particularly, to a charging cradle capable of charging and communicating via a power line, an electronic device including same, and a method for operating same.

### 2. Description of Related Art

Various types of electronic devices are being developed and distributed to meet the needs of users who want newer and more diverse functions. Recently, in addition to smartphones and tablet personal computers (PCs), the distribution of wearable electronic devices such as smartwatches, smart-earphones, or smart-glasses has been expanding.

For some electronic devices, electronic device manufacturers also provide, with an electronic device, a charging cradle (or charging stand, charging case, or charging device) that charges a battery of the electronic device or transmits and receives data between the electronic device and an external device. The charging cradle may charge the battery of an electronic device (e.g. wireless earphones) using power from an internal battery or an external power source connected by wire or wirelessly. The charging cradle may require data communication with the electronic device to display the state of the electronic device on the charging cradle.

The charging cradle does not provide wireless communication capabilities, and therefore power transmission and data communication may be accomplished through a wired transmission line (e.g., 1-wire communication, single wire interface (SWI) protocol) between the charging cradle and the electronic device. For example, the charging cradle may be formed to have connector pins for contacting connector terminals formed on at least a portion of the electronic device, and may transmit power to the electronic device or transmit and receive data with the electronic device through the connector pin.

The above information may be provided as a related art for the purpose of aiding understanding of the disclosure. No assertion or determination is made as to whether any of the above description can be applied as prior art relating to the disclosure.

### SUMMARY

In data communication between an electronic device (e.g., wireless earphones) and a charging cradle, the charging cradle may operate as the subject of communication. The charging cradle may control the output of a power line connected to the electronic device and initiate data communication with the electronic device by requesting communication from the charging cradle to the electronic device when communication is needed. On the other hand, in a case of an electronic device, a communication error may occur if communication with the charging cradle overlaps, so even if communication is needed in the electronic device, data communication is implemented to be enabled only when the charging cradle requests communication.

For example, while an electronic device is being charged, a charging cradle may temporarily block power transmission to the electronic device in order to perform data communication with the electronic device, then may change the voltage to a voltage suitable for communication and transmit a communication request signal to the electronic device, and may start data communication with the electronic device when the charging cradle receives a response signal indicating the presence of communication data based on the communication request signal from the electronic device.

Regarding the starting point of data communication, the electronic device can only start communication when the charging cradle requests the data communication. Accordingly, when the electronic device needs to stop charging the charging cradle or needs to communicate, the electronic device has to wait for the charging cradle to start communication, causing a problem of a communication delay. In addition, from the charging cradle's perspective, in order to determine whether the electronic device needs to communicate, a request signal has to be sent to the electronic device at regular intervals to determine whether a response signal is received, so there is a disadvantage in that charging is cut off at regular intervals.

One or more embodiments of the disclosure provide a charging cradle which can not only start communication while charging an electronic device, but also identify when communication is needed on the electronic device to reduce unnecessary communication procedures, shorten charging time, and reduce communication errors, an electronic device including same, a method of operating the same, and a non-transitory computer-readable recording medium.

The problems to be addressed in the present disclosure are not limited to the problem(s) mentioned above, and may be expanded in various ways without departing from the spirit and scope of the present disclosure.

According to an aspect of the disclosure, an electronic device includes: connector pins including a first pin and a second pin configured to transmit power or a communication signal; a power supply; a current detection sensor configured to detect charging current transmitted through the first pin; at least one processor including processing circuitry; a switch configured to connect one of the power supply and the at least one processor to the first pin; and memory configured to store instructions, wherein the instructions, when executed by the at least one processor individually or collectively, cause the electronic device to: based on connector terminals of a wearable device being connected to the connector pins, transmit the power to the wearable device through a first path connected to the first pin and the power supply; monitor the charging current of the first pin based on a measurement value provided by the current detection sensor; based on the charging current changing to be at or below a threshold, control the switch to connect the at least one processor to the first pin; and communicate data with the wearable device through a second path connected to the at least one processor and the first pin.

According to an aspect of the disclosure, a wearable device includes: connector terminals including a first terminal and a second terminal; a charger connected to a transmission line of the first terminal; a battery connected to the charger; at least one processor connected to the first terminal via the transmission line; and memory including instructions, wherein the instructions, when executed by the at least one processor individually or collectively, cause the wearable device to: charge the battery using power transmitted from an electronic device through the connector terminals based on being connected to a connector pin of the electronic device configured to supply the power through the connector terminals; identify at least one of a fully charged state, a coupling request state, a software update state, a true wireless stereo (TWS) communication state, or a battery heat state, as an identified state; and block a connection between the charger and the connector terminals based on identifying the identified state while the battery is charged.

According to an aspect of the disclosure, a method for operating an electronic device, includes: based on connector terminals of a wearable device contacting a connector pin of the electronic device, outputting power for charging a battery of the wearable device to the wearable device through a first path connected to a power supply and the connector pin of the electronic device; monitoring charging current transmitted through the connector pin; based on the charging current changing to be at or below a threshold, controlling a switch between the power supply and the connector pin to connect the connector pin to at least one processor of the electronic device through a second path; and communicating data with the wearable device through the second path.

According to an aspect of the disclosure, a method for operating a wearable device, includes: based on connector terminals of the wearable device contacting and connecting to a connector pin of an electronic device, charging a battery of the wearable device using power supplied from the electronic device; identifying at least one of a fully charged state, a coupling request state, a software update state, a true wireless stereo (TWS) communication state, or a battery heat state related to charge-blocking of the battery, as an identified state; and blocking charging of the battery by turning off a charger connected to the battery, based on identifying the identified state while the battery is charging.

An electronic device or wearable device according to one or more embodiments may include a non-transitory computer-readable medium storing instructions that, when executed by a processor, cause the electronic device or wearable device to perform operations included in a method of operating the electronic device or wearable device.

According to one or more embodiments, in a charging cradle and an electronic device, the charging cradle changes to a data communication mode with the electronic device only when the electronic device requires data communication with the charging cradle while the electronic device is charging, and thus, compared to a related art implementation method in which the charging cradle attempts communication by temporarily blocking charging by periodically forcibly lowering the charging voltage, the number of charging interruptions can be reduced and the increase in charging time can be reduced.

The effects that can be obtained from the disclosure are not limited to the effects mentioned above, and other effects not mentioned will be clearly understandable from the description below by those skilled in the art to which the disclosure belongs.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating an electronic device 101 in a network environment 100 according to one or more embodiments;

FIG. 2 illustrates a diagram for explaining a charging cradle and wearable devices according to one or more embodiments;

FIG. 3 illustrates configurations of a charging cradle and a wearable device according to one or more embodiments;

FIG. 4A illustrates a charging cradle and a method of operating a wearable device according to one or more embodiments;

FIG. 4B illustrates a charging cradle and a method of operating a wearable device according to one or more embodiments;

FIG. 5 shows a method of operating a charging cradle according to one or more embodiments; and

FIG. 6 illustrates a method of operating a wearable device according to one or more embodiments.

### DETAILED DESCRIPTION

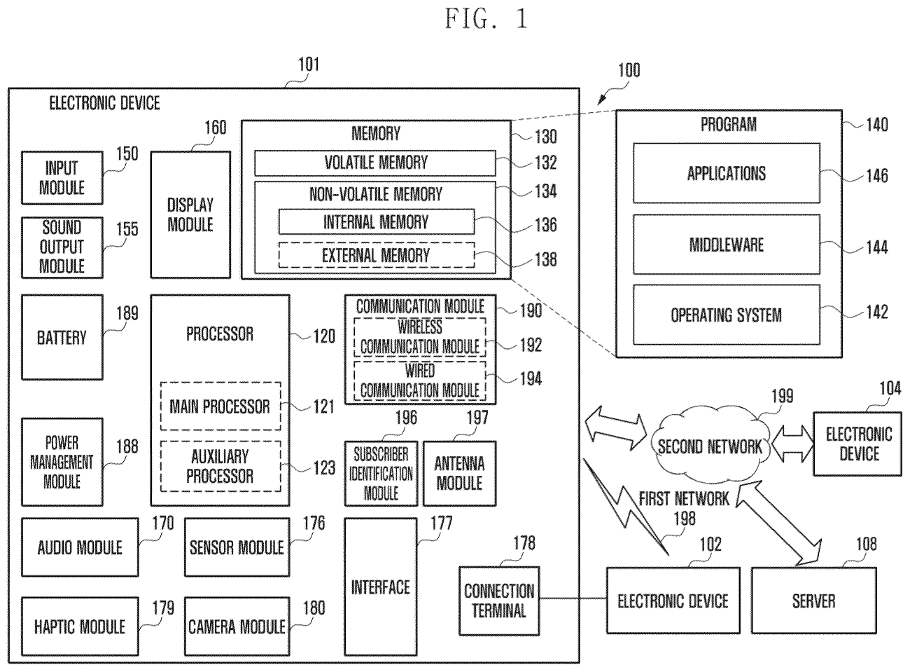

FIG. 1 is a block diagram illustrating an electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

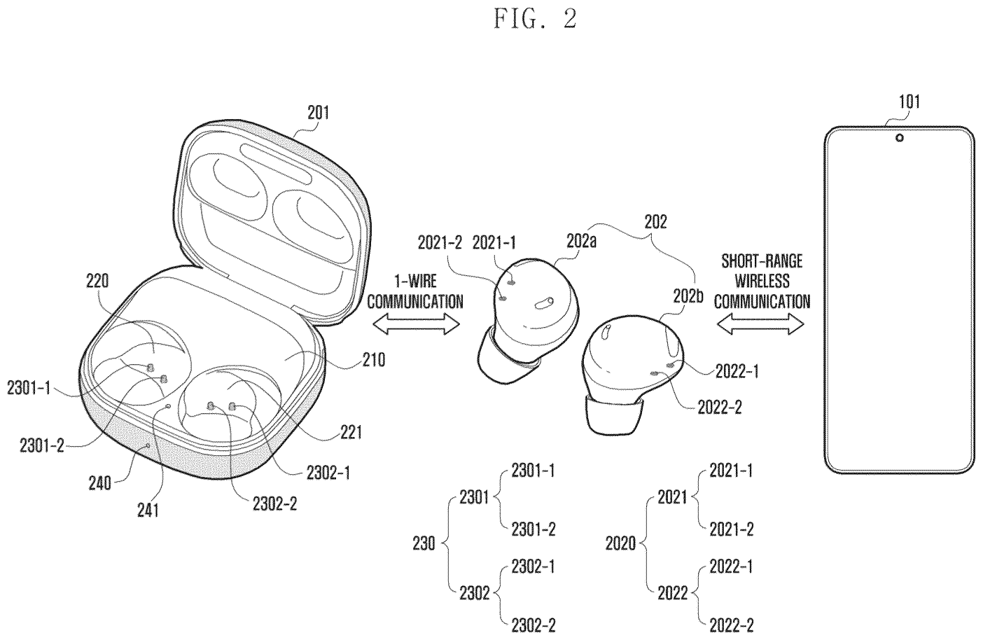

FIG. 2 illustrates a diagram for explaining a charging cradle and wearable devices according to one or more embodiments.

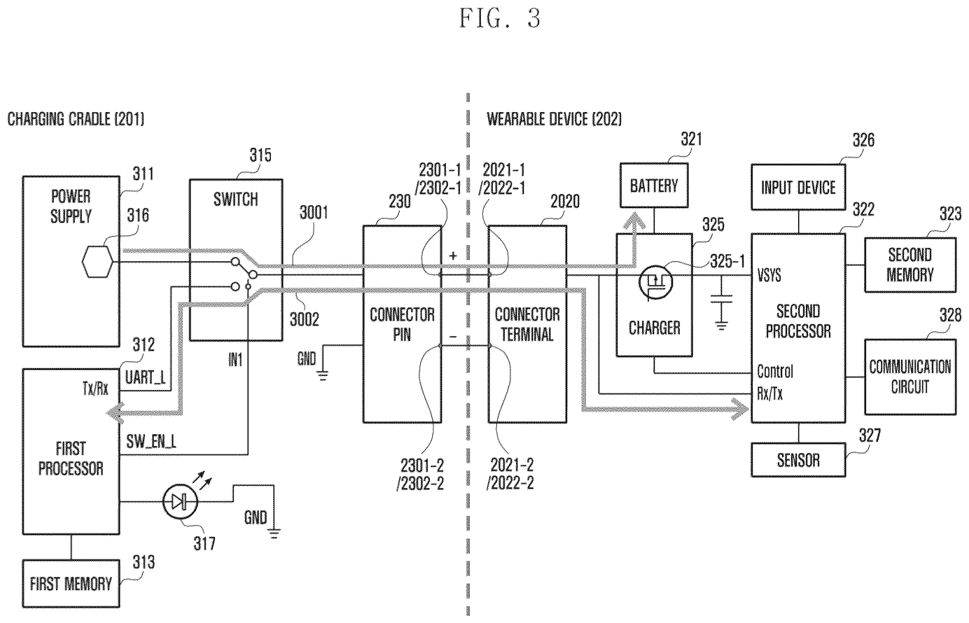

Referring to FIG. 2, according to one or more embodiments, wearable devices 202 (e.g., ear wearable devices) may be stored in a charging cradle 201, and a battery (e.g., a battery 321 of FIG. 3) of the wearable devices 202 may be charged through the charging cradle 201.

According to one or more embodiments, the wearable devices 202 may communicate with the electronic device 101 of FIG. 1 via a short-range wireless communication method and may communicate with the charging cradle 201 via a 1-wire communication method.

According to one or more embodiments, the wearable devices 202 may include a first device (e.g., a first device 202a) and a second device (e.g., a second device 202b). Each of the first device 202a or the second device 202b may independently perform the operations of the wearable devices 202, which will be described later. For example, in FIG. 2, the wearable devices 202 are described as ear wearable devices that are worn on the user's ears and output audio signals, but this is only an example. The wearable devices 202 may be a wireless wearable device, a wireless ear device, and a true wireless stereo (TWS) device, ear buds, wireless earphones, a wireless VR device, or an AR glasses device.

The wearable devices 202 illustratively shown in FIG. 2 may include a first device 202a that may be worn on a user's left ear and a second device 202b that may be worn on the user's right ear. The first device 202a and the second device 202b may be configured as one set. The wearable devices 202 may include a charging cradle 201 and connector terminals 2020 for electrical connection. The connector terminals 2020 may include first connector terminals 2021 in the first device 202a, and second connector terminals 2022 in the second device 202b. The wearable devices 202 may receive power and perform data communication from connector pins 230 (e.g., pogo pins) of the charging cradle 201 through the connector terminals 2020.

The wearable devices 202 may receive and output audio signals from the electronic device 101 through short-range wireless communication (e.g. Bluetooth, Wi-Fi Direct). In one or more embodiments, in the wearable devices 202, one device (e.g., one of the first device 202a or the second device 202b) operating as a primary device (or main device) may be connected to the electronic device 101 via short-range wireless communication, and the primary device may receive an audio signal from the electronic device 101 and provide the audio signal to the other device (e.g., the other of the first device 202a or the second device 202b) operating as a secondary device (or sub device).

In one or more embodiments, the first device 202a and the second device 202b may each be connected to the electronic device 101 via short-range wireless communication. The first device 202a and the second device 202b may each receive an audio signal from the electronic device 101.

The battery built in the wearable devices 202 (e.g., the battery 321 of FIG. 3) may be a rechargeable battery (e.g., a lithium-ion battery). The wearable devices 202 may charge the battery based on the power supplied from the charging cradle 201 through the connector terminals 2020 when inserted into the charging cradle 201.

The charging cradle 201 according to one embodiment may store the wearable devices 202 or mount the wearable devices 202 therein, and may be a device capable of charging the battery of the wearable devices 202 through at least one of the connector pins 230 or capable of data communication with the wearable devices 202. The charging cradle 201 may be referred to by other terms such as a cradle device, a charging case, a charging dock, a charging station, a charging base, or a power transmission device.

The charging cradle 201 may include a power supply (e.g., a power supply 311 of FIG. 3) (e.g., a battery, an external power interface, and/or a wireless charging interface). In a state where the wearable devices 202 are inserted/mounted/docked in the charging cradle 201, if the charging cradle 201 receives external power by wire or wirelessly, power may be supplied to the wearable devices 202 through the corresponding power source. If the charging cradle 201 is not connected to an external power source, the battery power of the charging cradle 201 may be supplied to the wearable devices 202.

The charging cradle 201 shown exemplarily in FIG. 2 may include a fixed assembly 210 including a first hole 220 and a second hole 221 capable of fixing the wearable devices 202, a first LED 240 (e.g., a display device 317 of FIG. 3) configured to display the charging/communication state of the charging cradle 201, and a second LED 241 configured to display the charging state of the wearable devices 202. The first hole 220 of the charging cradle 201 may include first connector pins 2301 for electrical connection with the first device 202a, and the second hole 221 may include second connector pins 2302 for electrical connection with the second device 202b. The connector pins 230 may have a contact pin structure such as pogo pins. Pogo pins may be physically or electrically connected to contact terminals (e.g. the connector terminals 2020) through a vertical spring structure.

The first connector pins 2301 and the second connector pins 2302 may include first pins (e.g., the positive pins 2301-1 and 2302-1) and second pins (e.g., the negative pins 2301-2 and 2302-2), respectively.

For example, when the first device 202a is inserted into the first hole 220, the first connector pins 2301 may be configured to contact the first connector terminals 2021 of the first device 202a, and when the second device 202b is inserted into the second hole 221, the second connector pins 2302 may be configured to contact the second connector terminals 2022 of the second device 202b, to form an electrical connection. The first connector terminals 2021 and the second connector terminals 2022 may also include first terminals (e.g., positive terminals 2021-1 and 2022-1) and second terminals (e.g., negative terminals 2021-2 and 2022-2), respectively. Charging and data communication may be performed through an electrical path connected according to the contact between the connector pins 230 of the charging cradle 201 and the connector terminals 2020 of the wearable devices 202. For example, the charging cradle 201 and the wearable devices 202 may transmit and receive data related to battery state, charging thermal state, and/or firmware updates, and examples of data communication are not limited thereto.

Each of the embodiments disclosed in FIGS. 3 to 6 described later may operate independently as one embodiment, or at least two embodiments may be combined to operate. When at least two embodiments operate in combination, at least some configurations and/or at least some operations included in each embodiment may be omitted.

FIG. 3 illustrates configurations of a charging cradle and a wearable device according to one or more embodiments.

Referring to FIG. 3, one or more embodiments may include a charging cradle (e.g., the charging cradle 201 of FIG. 2) configured to transmit power by using an external power source (e.g., wirelessly or by wire) or a battery, and a wearable device 202 configured to receive power from the charging cradle 201 and charging a battery by using the received power. The wearable device 202 shown in FIG. 3 may indicate the first device 202a or the second device 202b shown in FIG. 2.

According to one embodiment, the charging cradle 201 may include a power supply 311, a first processor 312, a first memory 313, connector pins 230, a switch 315, a current detection sensor 316, and a display device 317, but is not limited thereto, and may further include various configurations for power transmission and data communication.

The power supply 311 may include at least one of a battery, a wireless charging interface, and/or a wired charging interface (e.g., a universal serial bus (USB) port). The power supply 311 may convert power transmitted from a battery or/and an external power source (e.g., wireless charging interface or wired charging interface) into a predefined voltage (e.g., 5V), and may output the converted voltage to the connector pins 230. The power supply 311 may output the predefined voltage to a transmission line (e.g., the first pins (the positive pins 2301-1 and 2302-1)) of the connector pins, based on the connector pins 230 being in contact with the connector terminals 2020 of the wearable device 202.

The connector pins 230 may include contact pins such as pogo pins. The connector pins 230 may include, for example, first pins (e.g., the positive pins 2301-1 and 2302-1) configured to supply a high potential voltage and second pins (e.g., the negative pins 2301-2 and 2302-2) configured to supply a low potential voltage. The first pins (e.g., the positive pins 2301-1 and 2302-1) may be used as a transmission line (or single wire line) used for power transmission and data communication, and the second pins (e.g., the negative pins 2301-2 and 2302-2) may be connected to the ground.

The switch 315 may be switched so that the transmission line of the connector pins 230 is connected to either the first processor 312 or the power supply 311 according to an enable signal (or switch on/off signal) of the first processor 312. For example, the switch 315 may include a single pole double throw (SPDT) switch. In a power transmission section, the transmission line may be connected to a first path 3001 connecting the power supply 311 and the first pins (e.g., the positive pins 2301-1 and 2302-1) through the switch 315. In a data communication section, the transmission line may be connected to a second path 3002 connecting the first processor 312 and the first pins (e.g., the positive pins 2301-1 and 2302-1) through the switch 315.

The current detection sensor 316 (e.g., sensing resistor) may be placed between the switch 315 and the power supply 311. When transmitting power, the power supply 311 may pass through the current detection sensor 316 and the switch 315 and output power (e.g., charging current) through the connector pins 230. The current detection sensor 316 may detect the charging current flowing through the transmission line connected through the connector terminals 2020 and the connector pins 230 and may transmit the measured value to the first processor 312. For example, the current detection sensor 316 may sense current at both ends of a sensing resistor and may transmit a comparison value obtained by comparing the current obtained at both ends to the first processor 312. The first processor 312 may monitor changes in charging current of the connector pins 230 while transmitting power to the wearable device 202 through the connector pins 230. For example, the first processor 312 may monitor changes in charging current based on changes in the value detected by the current detection sensor 316 (e.g., sensing resistor).

In the example of FIG. 3, the current detection sensor 316 is shown as included in the power supply 311 connected to the switch 315, but in some cases, a resistor configured to sense the charging current may not be disposed inside the power supply 311, but may be disposed on the line (first path 3001) connecting the power supply 311 and the first pins (e.g., the positive pins 2301-1 and 2302-1) of the connector pins 230.

According to one or more embodiments, the current detection sensor 316 included in the power supply 311 may be omitted, and a resistor configured to sense the charging current may be disposed between the second pins (e.g., the negative pins 2301-2 and 2302-2)) and the ground. If the resistor configured to sense the charging current is disposed between the second pins (e.g., the negative pins 2301-2 and 2302-2) and the ground, the charging cradle 201 has the advantage of minimizing the number of pins of the first processor 312. The display device 317 (e.g., the first LED 240 and the second LED 241 in FIG. 2) may display information related to at least one of the charging state of the wearable device 202, the charging state of the cradle 201, or the state of communication with the wearable device 202.

The first memory 313 may include instructions executable by the first processor 312. Operations of the first processor 312 may be performed when executing instructions included in the first memory 313.

When controlling the overall operation of the charging cradle 201 and signal flow between components and executing instructions, the first processor 312 may perform operations related to the components of the charging cradle 201. For example, the first processor 312 may control the overall operations of the charging cradle 201, the operations being related to recognizing the wearable device 202 connected to the connector pins 230, transmitting power to the wearable device 202, data communication with the wearable device 202, and displaying the state of the wearable device 202 or the charging cradle 201.

The first processor 312 may detect that the wearable device 202 is connected/contacted (e.g., pogo-on state) to the connector pins 230, and may control the charging cradle 201 to operate in a battery charging mode. For example, the first processor 312 may identify whether the switch 315 is connected to the first path 3001 and may control the switch 315 so that the power supply 311 and the connector pins 230 are connected to the first path. The power supply 311 may transmit (or output) the output power to the wearable device 202 through the transmission line (e.g., the first path 3001) connected to the connector pins 230 and the power supply 311.

While power is transmitted by a connected transmission line (e.g., the first path 3001) connected to the power supply 311 and the connector pins 230, in a case where a change in which the charging current of the connector pins 230 falls to or below a predefined threshold is detected, the first processor 312 may recognize the charge-blocking state of the wearable device 202 or the starting timepoint of communication in the wearable device 202. For example, while a battery 321 of the wearable device 202 is charged by using the connector pins 230 and the connector terminals 2020, in a case where a wearable device 202 blocks, in a specific situation, the charger 325 which supplies voltage to the battery 321, the charging current flowing through the connector pins 230 and the connector terminals 2020 may fall to or below a configured threshold.

Based on the charging current of the connector pins 230 falling to or below the predefined range, the first processor 312 may control the switch 315 so that the transmission line of the connector pins 230 is connected to a transmission line (e.g., the second path 3002) connecting the first processor 312 and the connector pins 230. For example, the first processor 312 may recognize that the charging current of the connector pins 230 falls to or below a predefined range and the wearable device 202 is in a specific state related to charge-blocking, and may stand by in a data communication mode. In the data communication mode, the first processor 312 may turn on a UART port of the first processor 312. In the data communication mode, the first processor 312 may transmit data to the wearable device 202 by using a method that enables the current of the first pins (e.g., the positive pins 2301-1 and 2302-1) to have a current change corresponding to the predefined bit information, or may extract predefined bit information from a current change to obtain data transmitted from the wearable device 202.

The first processor 312 may recognize that the charging current of the connector pins 230 falls to or below a predefined range and the wearable device 202 is in a specific state related to charge-blocking, and then, the first processor may request state information from the wearable device 202 through the transmission line (e.g., first pin (2301-1, 2302-1)) of the second path 3002 connected to the first processor 312 and the connector pins 230. The first processor 312 may receive state information of the wearable device 202 through the connector pins 230. For example, the state information may include at least one of a fully charged battery state, a battery heat state, a coupling request state, a firmware update request state, or a true wireless stereo (TWS) communication request state of the wearable device 202.

The first processor 312 may perform a predefined function in response to the state information of the wearable device 202 and may output information (e.g., color, sound, or text) guiding the predefined function through the display device 317. As an example, the first processor 312 may control the display device 317 (e.g., an LED device) to output a red color when the battery is charging, or may control the display device 317 to display a green color when the battery is fully charged. As another example, the first processor 312 may control the display device 317 to display a yellow color when the state information transmitted from the wearable device 202 indicates a battery heat condition. Alternatively, the first processor 312 may control the display device 317 to output a blue color when the state information transmitted from the wearable device 202 is in a firmware update request state. The user may recognize subsequent operations of the charging cradle 201 and the wearable device 202 through the information (or color) displayed on the display device 317 of the charging cradle 201.

The wearable device 202 shown in FIG. 3 is an example of either the first device 202a or the second device 202b in FIG. 2.

According to one or more embodiments, the wearable device 202 is capable of receiving power and data communication through connector terminals (or contact terminals) 2020, and may be stored/mounted/docked in a charging cradle 201. The wearable device 202 shown exemplarily in FIG. 3 may include a battery 321, a second processor 322, a second memory 323, connector terminals 2020, a charger 325, an input device 326, a sensor 327, and a communication circuit 328, but may include at least one of the configurations and/or functions described in FIG. 1 or FIG. 2 in addition to the shown configuration.

The battery 321 may be a rechargeable battery. The battery 321 may be charged based on the power delivered through the connector terminals 2020.

The connector terminals 2020 may include first terminals (e.g., positive terminals 2021-1 and 2022-1) and second terminals (e.g., negative terminals 2021-2 and 2022-2) configured to physically contact connector pins 230 of the charging cradle 201 while the wearable device 202 is stored/held/docked in the charging cradle 201. The first terminals (e.g., the positive terminals 2021-1 and 2022-1) may be in physical contact with the first pins (e.g., the positive pins 2301-1 and 2302-1) of the connector pins 230, and the second terminals (e.g., the negative terminals 2021-2 and 2022-2) may be in physical contact with the second pins of the connector pins 230 (e.g., the negative pins 2301-2 and 2302-2).

The transmission line of the connector terminals 2020 may be branched into the first path 3001 which is connected to the charger 325, and the second path 3002 which is connected to the second processor 322 for battery charging.

The charger 325 may be electrically connected to the battery 321 and the second processor 322 and may include a power switch 325-1. For example, the charger 325 may be implemented as at least a part of a power management integrated circuit (PMIC), but is not limited thereto. The charger 325 may convert the power transmitted from the connector terminals 2020 into a predefined charging current and may transfer the charging current to the battery 321 to charge the battery 321. The charger 325 may adjust at least one of the charging current and charging voltage of the battery 321 by using power transmitted from the connector terminals 2020. The second processor 322 may charge the battery 321 or block charging of the battery 321 by turning on/off the power switch 325-1 of the charger 325 through a control signal.

According to one or more embodiments, the wearable device 202 may recognize the voltage value of the power flowing from the charger 325 through the first terminals (e.g., the positive terminals 2021-1 and 2022-1) and may determine whether to transmit the transmitted voltage to the battery. If the voltage delivered through the first terminals (e.g., the positive terminals 2021-1 and 2022-1) is above a predefined voltage value (e.g. UVLO: under voltage lock out), the charger 325 may transmit voltage to the second processor 322 or the battery 321 connected to the charger 325, and if the delivered voltage is equal to or below a predefined voltage value, the charger 325 may not transmit the voltage. The voltage transmitted to the first path 3001 may be supplied through the power supply 311, and thus may be supplied at or above a predefined voltage value (e.g. UVLO: under voltage lock out). The voltage coming to the Rx/Tx pin of the UART through the first path 3001 may be blocked inside the second processor 322. On the other hand, the voltage transmitted to the second path 3002 may be lower than the voltage transmitted to the first path 3001, and thus the voltage may not pass through the charger 325 and may be transmitted through the UART port (Rx/Tx pin) of the second processor 322. The input device 326 may receive user input from the outside (e.g., a user). For example, the input device 326 may include a touch input device or a physical key/button device, but is not limited thereto.

The sensor 327 may include at least one sensor that detects the user's biometric information, the wearable device 202, or the user's movement information. The sensor 327 may include at least one of a gesture sensor, a voice recognition sensor, a magnet pattern sensor, a touch sensor, and a force sensor, but this is only an example and is not limited thereto. The sensor 327 may transmit measured values detected through at least one sensor to the second processor 322.

The communication circuit 328 may support short-range wireless communication. The communication circuit 328 may form a short-distance communication link with the electronic device 101 of FIG. 1 and may support transmitting and receiving various data (e.g., audio signals) with the electronic device 101. The communication circuit 328 may support short-range wireless communication. Short-range wireless communication may include Bluetooth, Bluetooth Low Energy (BLE), Wi-Fi, adaptive network topology (ANT+), long term evolution (LTE), 5th generation mobile telecommunication (5G), and/or narrowband internet of things (NB-IoT). In some embodiments, the communication circuit 328 may be connected to an access point (AP) or another network through short-range wireless communication. For example, the communication circuit 328 may receive firmware update information or audio signals of the electronic device 101, the charging cradle 201, and/or the wearable device 202.

The second memory 323 may include instructions executable by the second processor 322. Operations of the second processor 322 may be performed when executing instructions included in the second memory 323.

The second processor 322 may control the overall operation of the wearable device 202 and signal flow between components and may perform operations related to the components of the wearable device 202 when executing instructions. For example, the second processor 322 may control the overall operation of the wearable device 202 such as recognizing the charging cradle 201 connected through the connector terminals 2020, charging the battery 321, blocking charging of the battery 321, and transmitting and receiving data with the charging cradle 201.

The second processor 322 may control the power switch 325-1 within the charger 325 to charge the battery 321 (e.g., charging mode) through a transmission line connected to the connector terminals 2020, or to communicate data with the charging cradle 201 (e.g., data communication mode). For example, the charging mode may be a mode in which the battery 321 is charged using power transmitted through the connector terminals 2020, and the data communication mode may be a mode in which data is transmitted and received with the charging cradle 201 using the terminal through which power is received without charging the battery 321 by turning off/disabling the charger 325.

The second processor 322 may control the charger 325 to be turned on/activated based on the connector terminals 2020 being connected/contacted with the connector pins 230 of the charging cradle 201 so that the power received through the connector terminals 2020 passes through the charger 325 and is supplied to the battery 321. For example, the second processor 322 may turn on the power switch 325-1 to turn on the charger 325. The UART port (Rx/Tx pin) of the second processor 322 may be in an off state.

The second processor 322 may recognize a specific state related to charge-blocking, for example, at least one of a fully charged state, a coupling request state, a firmware update state, a TWS communication request state, or a battery heat state. The second processor 322 may recognize a specific state related to charge-blocking based on data/information transmitted from the communication circuit 328, the input device 326, or the sensor 327 (e.g., at least one of a temperature detection sensor, a gesture sensor, a voice recognition sensor, a magnetic pattern recognition sensor, a touch sensor, or a force sensor).

The second processor 322 may turn off/disable the charger 325 to notify the charging cradle 201 of a battery charge blocking state and/or the starting timepoint of communication with the wearable device 202 based on the recognition of a specific condition related to charge-blocking. For example, the second processor 322 may turn off the power switch 325-1 to turn off the charger 325. As the power switch 325-1 is turned off, the electrical path configured to connect the charger 325 and the battery 321 may be cut off, and thus charging of the battery 321 may be blocked.

As an example, the second processor 322 may detect user input to request a coupling connection based on the input device 326 or the sensor 327 (e.g., at least one of a gesture sensor, a voice recognition sensor, a magnetic pattern recognition sensor, a touch sensor, or a force sensor), and in a case where coupling is requested by user input, charging of the battery 321 may be blocked by turning off the charger 325. As another example, in a case where a firmware update request or a TWS communication request is made based on data received through the communication circuit 328, the second processor 322 may turn off the charger 325 to block charging of the battery 321. As another example, the second processor 322 may monitor the heat state of the battery 321 through the sensor 327 (e.g., temperature detection sensor), and in a case where the heating temperature of the battery 321 exceeds the configured temperature, the second processor 322 may turn off the charger 325 to block charging of the battery 321.

In a case where the charger 325 is turned off, the voltage transmitted through the connector terminals 2020 may be transmitted to the second processor 322 through the second path 3002 branched from the connector terminals 2020. In other words, the second processor 322 may be connected connector terminals 2020 via second path 3002. In data communication mode, the second processor 322 may transmit data with the charging cradle 201 by using a method that enables the current of the connector terminals 2020 (e.g., the first terminals (e.g., the positive terminals 2021-1 and 2022-1)) to have a current change corresponding to the predefined bit information, or the second processor 322 may extract the predefined bit information from current changes to obtain data transmitted from the charging cradle 201.

In a case where the charger 325 is turned off, the charging current flowing to the connector terminals 2020 may fall to or below a predefined threshold because charging of the battery 321 is blocked. While the charging cradle 201 is charging the battery 321 of the wearable device 202, in a case where a change in which the charging current flowing to the connector pins 230 connected to the connector terminals 2020 has fallen to or below a predefined threshold is detected, the charging cradle may recognize that a charge-blocking state has occurred in the wearable device 202.

The second processor 322 may turn off the charger 325 based on recognition of a specific state related to charge-blocking of the battery 321 and notify the charging cradle 201 of the charge-blocking state/or data communication starting timepoint, and then the second processor may switch the UART port to on-state to wait in the data communication mode. In a case where a state information request signal is received from the charging cradle 201, the second processor 322 may transmit the recognized specific state information to the charging cradle 201, and may perform a predefined function in response to the recognized specific state. For convenience of explanation, coupling may indicate connecting two devices in the absence of a promised device, and pairing may indicate connecting through wireless communication between two devices.

For coupling connection, the first device 202a and the second device 202b of the wearable device 202 may input signals for coupling to the charging cradle 201. The first device 202a may start communication with the charging cradle 201 after turning off the charger 325 and may transmit the Bluetooth identification (BT ID) of the first device 202a to the charging cradle 201. The second device 202b may also start communication with the charging cradle 201 after turning off the charger 325 and may transmit the BT ID of the second device 202b to the charging cradle 201. The charging cradle 201 may transmit the received BT identification (ID) of the first device 202a to the second device 202b, and may transmit the BT ID of the second device 202b to the first device 202a. The first device 202a and the second device 202b can complete coupling using the other party's BT ID.

An electronic device (e.g., the charging cradle 201) according to one or more embodiments may include connector pins 230 including first pins (e.g., the positive pins 2301-1 and 2302-1) and second pins (e.g., the negative pins 2301-2 and 2302-2) configured to transmit power or communication signals. An electronic device (e.g., the charging cradle 201) according to one or more embodiments may include a power supply (e.g., the power supply 311 of FIG. 3). An electronic device (e.g., the charging cradle 201) according to one or more embodiments may include a current detection sensor (e.g., the current detection sensor 316 of FIG. 3) configured to detect the charging current transmitted through the first pins (e.g., the positive pins 2301-1 and 2302-1). An electronic device (e.g., the charging cradle 201) according to one or more embodiments may include a processor (e.g., the first processor 312 of FIG. 3) including processing circuitry. An electronic device (e.g., the charging cradle 201) according to one or more embodiments may include a switch (e.g., the switch 315 of FIG. 3) configured to connect one of the power supply and the processor to the first pins (e.g., the positive pins 2301-1 and 2302-1). An electronic device (e.g., the charging cradle 201) according to one or more embodiments may include a memory (e.g., the first memory 313 of FIG. 3) configured to store instructions executable by the processor. When executed by the processor, based on that the connector terminals 2020 of the wearable device 202 are contacted and connected to the connector pins 230, the instructions according to one or more embodiments may enable the electronic device (e.g., the charging cradle 201) to transmit power to the wearable device 202 through a first path connected to the first pins (e.g., the positive pins 2301-1 and 2302-1) and the power supply. The instructions according to one or more embodiments may enable (or cause) the electronic device (e.g., the charging cradle 201) to monitor the charging current of the first pins (e.g., the positive pins 2301-1 and 2302-1), based on the measurement value transmitted from the current detection sensor. The instructions according to one or more embodiments may enable the electronic device (e.g., the charging cradle 201) to control the switch to connect the processor and the first pins (e.g., the positive pins 2301-1 and 2302-1), in a case where the monitored charging current changes to or below the configured threshold. The instructions according to one or more embodiments may enable the electronic device (e.g., the charging cradle 201) to perform data communication with the wearable device through a second path connected to the processor and the first pins (e.g., the positive pins 2301-1 and 2302-1).

The instructions according to one or more embodiments may enable the electronic device (e.g., the charging cradle 201) to request state information of the wearable device 202 from the wearable device 202. The instructions according to one or more embodiments may enable the electronic device (e.g., the charging cradle 201) to receive state information of the wearable device from the wearable device 202. The instructions according to one or more embodiments may enable the electronic device (e.g., the charging cradle 201) to perform a predefined function in response to the received state of the wearable device 202.

The instructions according to one or more embodiments may enable the electronic device (e.g., the charging cradle 201) to display, on a display device (e.g., the display device 317 of FIG. 3), the charging state of the electronic device (e.g., the charging cradle 201), the operating state of the electronic device (e.g., the charging cradle 201), and/or predefined information related to the charging state or operating state of the wearable device 202.

The current detection sensor according to one or more embodiments may be disposed inside the power supply or disposed on a path configured to connect the power supply and the first pins (e.g., the positive pins 2301-1 and 2302-1).

The current detection sensor according to one or more embodiments may be disposed in a path configured to connect the second pins (e.g., the negative pins 2301-2 and 2302-2) and the ground.

The current detection sensor according to one or more embodiments may sense the current at both ends (or two ends) of a sensing resistor and may transmit a value obtained by comparing the current at both ends of the sensing resistor to the processor.

A wearable device 202 according to one or more embodiments may include connector terminals 2020 including first terminals (e.g., positive terminals 2021-1 and 2022-1) and second terminals (e.g., negative terminals 2021-2 and 2022-2). The wearable device 202 according to one or more embodiments may include a charger (e.g., the charger 325 of FIG. 3) connected to the transmission line of the first terminals (e.g., the positive terminals 2021-1 and 2022-1). The wearable device 202 according to one or more embodiments may include a battery (e.g., the battery 321 of FIG. 3) connected to the charger. The wearable device 202 according to one or more embodiments may include a processor (e.g., the second processor 322 of FIG. 3) that branches off from the transmission line and is connected to the first terminals (e.g., positive terminals 2021-1 and 2022-1) and a memory (e.g., the second memory 323 of FIG. 3) including instructions executable by the processor. The instructions according to one or more embodiments may enable the wearable device 202 to charge the battery, when executed by the processor, based on the contact and connection with the connector pins 230 of the electronic device (e.g., the charging cradle 201) configured to supply power through the connector terminals 2020, by using the power transmitted from the electronic device (e.g., the charging cradle 201) through the connector terminals 2020. The instructions according to one or more embodiments may enable the wearable device 202 to block the connection between the charger and the connector terminals, in a state of charging the battery, based on that at least one of a fully charged state, a coupling request state, a software update state, a TWS communication state, or a battery heat state is identified.

The instructions according to one or more embodiments may enable the wearable device 202 to turn off the power switch to block the connection between the charger and the connector terminals and transmit and receive data through a path connected to the processor and the connector terminals of the wearable device.

The instructions according to one or more embodiments may enable the wearable device 202 to detect a user input requesting coupling based on at least one of the input device, a gesture sensor, a voice recognition sensor, a magnetic pattern recognition sensor, a touch sensor, or a force sensor, and to block the connection between the charger and the connector terminals based on the recognition of the coupling request state requested by the user input.

According to one or more embodiments, the wearable device 202 may include a communication circuit (e.g., the communication circuit 328 in FIG. 3), and the instructions may enable the wearable device 202 to be connected to an external electronic device (e.g., the electronic device 101 in FIG. 1) through short-range wireless communication through the communication circuit, and to recognize that the software update state or the true wireless stereo (TWS) communication state has occurred, based on data received from the external electronic device (e.g., the electronic device 101 in FIG. 1) through the communication circuit.

The wearable device 202 according to one or more embodiments may further include a temperature detection sensor. The instructions according to one or more embodiments may enable the wearable device 202 to identify the battery heat state by monitoring the heat state of the battery through the temperature detection sensor.

The instructions according to one or more embodiments may enable the wearable device 202 to transmit information or data related to the identified state to the electronic device (e.g., the charging cradle 201) through a path connected to the processor and the connector terminals 2020 of the wearable device 202.

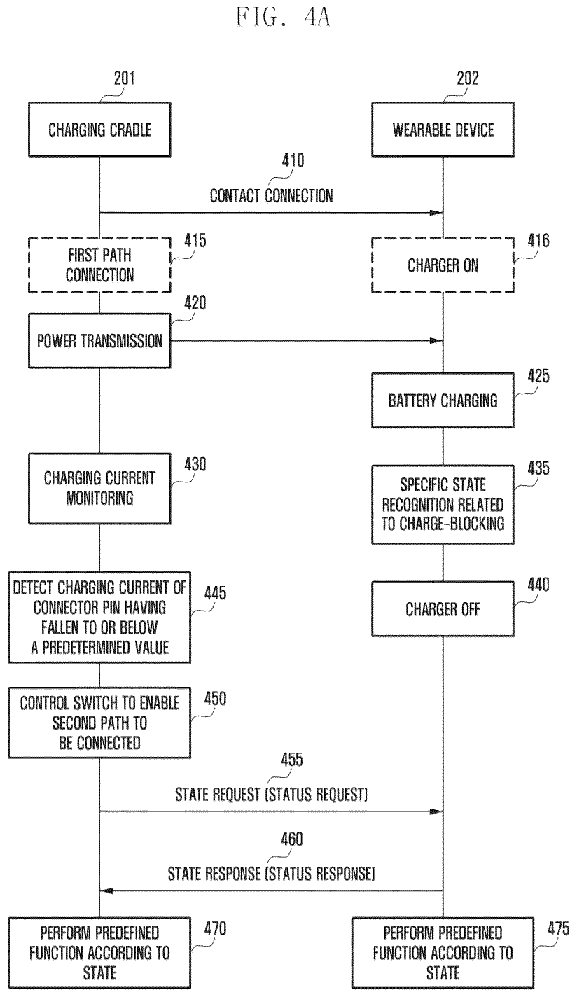

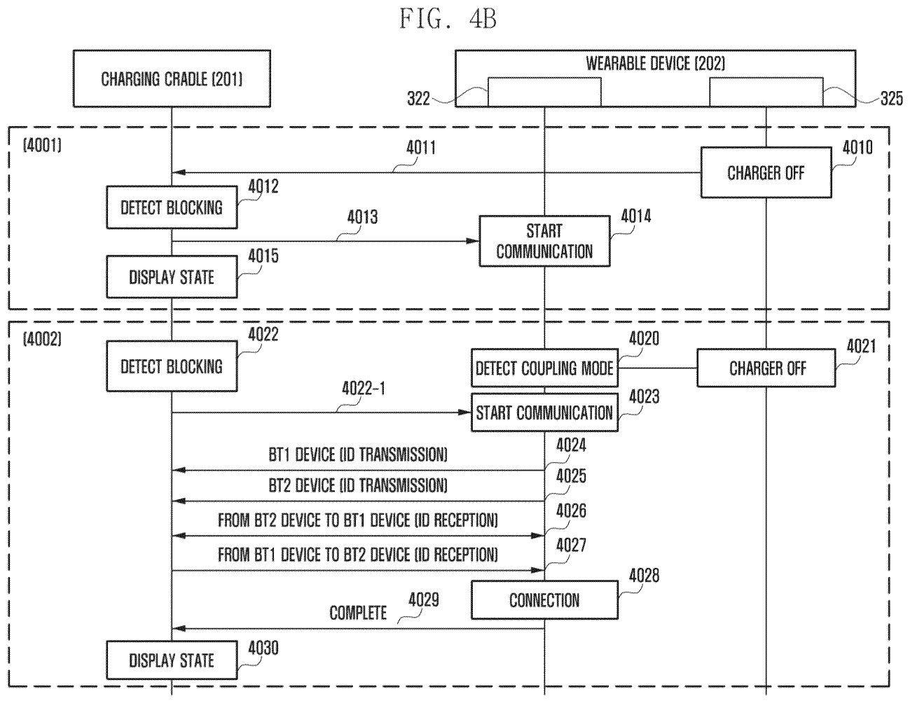

In the embodiments described below with reference to FIGS. 4A to 6, each operation may be performed sequentially, but may not be necessarily performed sequentially. For example, the order of each operation may be changed, and at least two operations may be performed in parallel. A wearable device 202 and a charging cradle 201 shown in FIGS. 4A to 6 may be the same as the wearable device 202 and the charging cradle 201 shown in FIGS. 2 to 3.

FIG. 4A and FIG. 4B illustrate a charging cradle and a method of operating a wearable device according to one or more embodiments.

Referring to FIG. 4A and FIG. 4B, according to one or more embodiments, the charging cradle 201 and the wearable device 202 may be contacted and connected through the connector pins 230 and the connector terminals 2020 in operation 410.

The wearable device 202 and the charging cradle 201 may each determine (or detect, sense) that the wearable device and the charging cradle are connected to each other through physical contact with the connector terminals 2020 and the connector pins 230.

In operation 415, the charging cradle 201 may identify whether the wearable device 202 is connected to the first path 3001 (e.g., the path of FIG. 3 connected to the power supply 311 and the connector pins 230) based on that the wearable device is contacted and connected through the connector pins 230 and may control a switch (e.g., the switch 315 in FIG. 3) to enable the wearable device to be connected to the first path. Alternatively, the charging cradle 201 may be configured to be connected to the first path by default.

According to one or more embodiments, operation 415 may be omitted.

In operation 416, the wearable device 202 may turn on the charger (e.g., the charger 325 of FIG. 3) based on that the charging cradle 201 is contacted and connected through the connector terminals 2020. The wearable device 202 may branch off from the connector terminals 2020 and the charger to turn off the UART port connected to the processor (e.g., the second processor 322 of FIG. 3). Accordingly, the voltage flowing into the processor (e.g., the second processor 322) through the connector terminals 2020 may be blocked inside the processor (e.g., the second processor 322).

According to one or more embodiments, operation 416 may be omitted.

In operation 420, the charging cradle 201 may output/transmit power transmitted from the power supply to the connector pins 230, based on the transmission line connected to the power supply (e.g., the power supply 311 of FIG. 3) and the switch (e.g., the switch 315 of FIG. 3). For example, the charging cradle 201 may use power supplied from a battery or an external power supply device (e.g., a travel adapter (TA), or a wireless charger) to produce charging current to a voltage level corresponding to the wearable device 202, and may output the produced charging current through the first pins (e.g., the positive pins 2301-1 and 2302-1) which are transmission lines.

In operation 425, the wearable device 202 may charge a battery (e.g., the battery 321 of FIG. 3) based on power transmitted through the connector terminals 2020 in contact with the connector pins 230. For example, the charger of the wearable device 202 may use power (e.g., current/voltage) transmitted through the transmission line of the connector terminals 2020 and convert the power into a charging current corresponding to the battery voltage, and may transmit the charging current to the battery of the wearable device 202.

In operation 430, the charging cradle 201 may monitor the charging current output through the connector pins 230 through a current detection sensor (e.g., the current detection sensor 316 of FIG. 3) disposed between the power supply and the switch. For example, the charging cradle 201 may detect a change in charging current output through the current detection sensor and may determine whether the changing charging current falls to or below a configured threshold.

In operation 435, the wearable device 202 may recognize a specific state related to battery charge-blocking while charging the battery. For example, the wearable device 202 may recognize or identify a specific state related to battery charge-blocking, for example, at least one of a fully charged state, a coupling request state, a software update state, a TWS communication request state, or a battery heat state as an identified state.

In operation 440, the wearable device 202 may turn off the charger to notify the charging cradle 201 that communication is required based on the recognition or identification of a specific state (identified state) related to charge-blocking. For example, the wearable device 202 may turn off the power switch (e.g., the power switch 325-1 of FIG. 3) in the charger to block the transmission line for battery charging. In a case where the charger is turned off, the charging current supplied to the battery may fall to or below a configured threshold. The charging cradle 201 may detect a change in charging current flowing through the connector pins 230 connected to the connector terminals 2020.

In operation 445, the charging cradle 201 may detect that the change in charging current of the connector pins 230 measured through the current detection sensor falls to or below a predefined threshold. In a case where the charging current of the connector pins 230 falls to or below a predefined threshold, the charging cradle 201 may recognize the wearable device 202 to be in a battery charging cutoff state or/and a communication start state.

In operation 450, the charging cradle 201 may control a switch so that the transmission line is connected to a second path (e.g., the second path 3002 in FIG. 3) connected to the switch and the first processor (e.g., the first processor 312 in FIG. 3), based on that the charging current change has fallen to or below a predefined threshold. The charging cradle 201 may control the switch to be connected to the second path and may turn on the UART port of the first processor to stand by in data communication mode.

In operation 455, the charging cradle 201 may request state information related to battery blocking in the wearable device 202 through the connector pins 230 connected to the second path. For example, the charging cradle 201 may transmit data requesting state information to the wearable device 202 through the transmission line (e.g., the second path), by using a method that causes the current of the first pins (e.g., the positive pins 2301-1 and 2302-1) to have a current change corresponding to the predefined bit information.

In operation 460, the wearable device 202 may transmit state information corresponding to a specific recognized state in response to a state request to the charging cradle 201.

In operation 470, the charging cradle 201 may perform a predefined function according to state information transmitted from the wearable device 202. In operation 475, the wearable device 202 may perform a predefined function depending on a specific recognized state related to battery charge-blocking.

According to one or more embodiments, examples of functions predefined according to states related to battery blocking in the charging cradle 201 and the wearable device 202 may be as shown in [Table 1] below, but these are only examples, and are not limited thereto.

TABLE 1

| | State type | Charging Cradle | Wearable Device |
|---|---|---|---|
| 1 | Charger done | Fully charged state LED indication | Charger off |
| | | | Contact signal transmission |
| 2 | Coupling mode | Coupling progress LED indication, | Charger off |
| | | Transmission of coupling connection | Coupling connection with opposite device |
| | | address of opposite device | |
| 3 | Battery high temp. | Battery heat state LED indication | Charger off |
| | | | After checking battery temperature, |
| | | | recharge battery, |
| | | | When recharging, information on |
| | | | charging state is transmitted |
| 4 | SW update | Firmware update progress LED | Charger off |
| | | indication | Transfer software delivered from external |
| | | | electronic device to cradle |
| 5 | TWS communication | TWS communication state led | Charger off |
| | | indication | TWS communication process |

With reference to FIG. 4B, predefined operations according to a fully charged state and coupling request state will be described by way of example. While displaying the fully charged state through the display device, the charging cradle 201 has to turn off the display device when the wearable device 202 is separated from the charging cradle 201, and thus it is necessary to monitor whether the charging cradle is in contact with the wearable device 202.

As shown in <4001>, in a case where the wearable device 202 inserted into the charging cradle 201 is fully charged, the wearable device 202 may turn off the charger (e.g., the charger 325 of FIG. 3) in operation 4010. In operation 4011, the wearable device 202 may transmit fully charged battery information to the charging cradle 201. In operation 4012, the charging cradle 201 may detect charge-blocking in the wearable device 202 according to the charger 325 being turned off. In operation 4013, the charging cradle 201 may control the switch 315 to be connected to the second path for data communication based on detection of charge-blocking. In operation 4013, the charging cradle 201 may transmit a start packet for data communication (e.g., a packet notifying the start of communication) to the wearable device. In operation 4014, the wearable device 202 may start data communication with the charging cradle 201 based on receiving the start packet for data communication (e.g., the packet notifying the start of communication) from the charging cradle 201. In operation 4015, the charging cradle 201 may display the state of the wearable device (e.g., fully charged state or another state) based on data communication with the wearable device 202.

As shown in <4002>, the wearable device 202 may detect the coupling mode by inputting a coupling request through a processor (e.g., the second processor 322 of FIG. 3) in operation 4020. In operation 4021, the wearable device 202 may turn off the charger 325. In operation 4022, the charging cradle 201 may detect charge-blocking in the wearable device 202 according to the charger 325 being turned off. The charging cradle 201 may control the switch 315 to be connected to a second path for data communication based on detection of charge-blocking. In operation 4022-1, the charging cradle 201 may transmit a start packet for data communication (e.g., a packet notifying the start of communication) to the wearable device. In operation 4023, the wearable device 202 may start data communication with the charging cradle 201 based on receiving the start packet for data communication (e.g., the packet notifying the start of communication) from the charging cradle 201. In operation 4024, the wearable device 202 may transmit the BT ID of the first device 202a (e.g., the BT ID of the first device) for coupling connection. In operation 4025, the wearable device 202 may transmit the BT ID of the second device 202b. In operation 4026, the charging cradle 201 may transmit the BT ID of the second device 202b to the first device 202a. The first device 202a may identify the BT ID of the second device 202b transmitted from the charging cradle 201. In operation 4027, the charging cradle 201 may transmit the BT ID of the first device 202a to the second device 202b. The second device 202b may identify the BT ID of the first device 202atransmitted from the charging cradle 201. In operation 4028, the wearable device 202 may perform a coupling connection between the first device 202a and the second device 202b by using the BT ID of the first device 202a and the BT ID of the second device 202b. In operation 4029, the wearable device 202 may transmit coupling completion information to the charging cradle 201 based on completion of the coupling connection. In operation 4030, the charging cradle 201 may display the state of the wearable device (e.g., coupling completion state) through coupling completion information based on data communication.

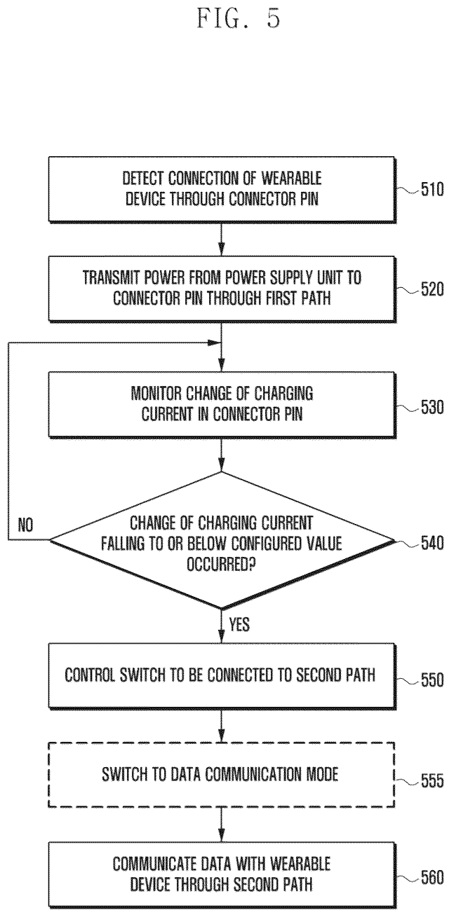

FIG. 5 shows a method of operating a charging cradle according to one or more embodiments.

Referring to FIG. 5, the charging cradle 201 according to one or more embodiments may detect a contact connection with the wearable device 202 through the connector pins 230 in operation 510. The charging cradle 201 may detect that the connector pins 230 and the connector terminals 2020 of the wearable device 202 are connected to each other through physical contact therebetween.

In operation 520, the charging cradle 201 may transmit (or output or supply) power supplied from the power supply to the wearable device 202 through a first path (e.g., the first path 3001 of FIG. 3) connected to a power supply (e.g., the power supply 311 of FIG. 3) and a switch (e.g., the switch 315 of FIG. 3) based on that the wearable device 202 is connected/contacted to the charging cradle through the connector pins 230. The charging cradle 201 may supply power to the wearable device 202 through the transmission line of the connector pins 230 connected to the first path.

For example, when the charging cradle 201 receives power from an external power source by wire or wirelessly, the charging cradle may supply power to the wearable device 202 through the external power source. In a case where the charging cradle 201 is not connected to an external power source, the battery power of the charging cradle 201 may be supplied to the wearable device 202.

In operation 530, the charging cradle 201 may monitor a change in charging current of the connector pins 230. For example, the charging cradle 201 may monitor a change in the charging current of the connector pins based on a current detection sensor disposed between the power supply and the switch (e.g., the current detection sensor 316 of FIG. 3) or a current detection sensor disposed on the ground line of the connector pins 230.

In operation 540, the charging cradle 201 may determine whether a change in which the charging current of the connector pins 230 falls to or below a set threshold occurs.

In operation 550, in a case where the charging current of the connector pins 230 falls to or below the configured threshold (in operation 540, YES), the charging cradle 201 may control the switch so that the processor (e.g., the first processor 312 of FIG. 3) and the connector pins 230 are connected to a second path (e.g., the second path 3002 of FIG. 3).

In a case where no change occurs, which causes the charging current of the connector pins 230 to fall to or below the configured threshold (in operation 540, NO), the charging cradle 201 may return to operation 530 to monitor a change in charging current of the connector pins.

In operation 555, the charging cradle 201 may recognize that the charging current of the connector pins 230 falls to or below a predefined range and the electronic device is in a specific state related to charge-blocking and may stand by in a data communication mode (e.g., Rx mode). For example, the charging cradle 201 may turn on the UART port of the processor connected to the switch.

According to one or more embodiments, operation 555 may be omitted.

In operation 560, the charging cradle 201 may communicate data with the wearable device 202 through a transmission line of the second path connected to the processor and the connector pins 230. For example, the charging cradle 201 may transmit data to the wearable device 202 by using a method that causes the current of the first pins (e.g., the positive pins 2301-1 and 2302-1) to have a current change corresponding to the predefined bit information, or may obtain data transmitted from the wearable device 202 by extracting predefined bit information from changes in current.

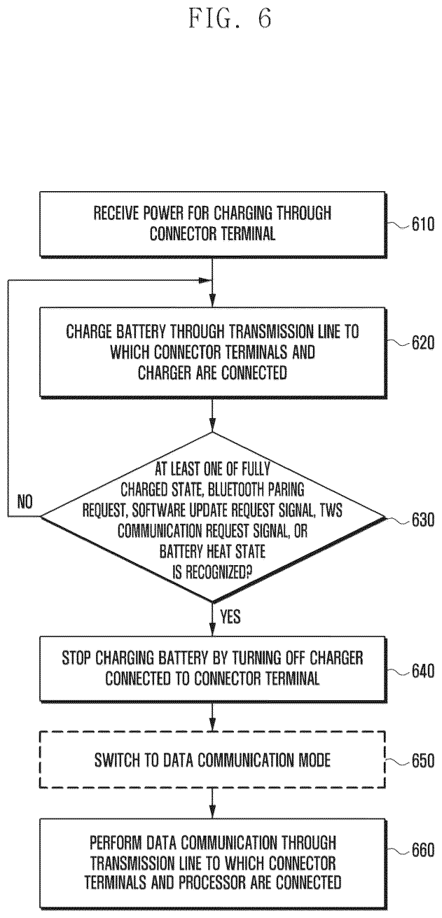

FIG. 6 illustrates a method of operating a wearable device according to one or more embodiments.

Referring to FIG. 6, a wearable device 202 according to one or more embodiments may receive power for charging a battery (e.g., the battery 321 in FIG. 3) through connector terminals 2020 in operation 610.

In operation 620, the wearable device 202 may charge the battery through a transmission line connected to the connector terminals 2020 and a charger (e.g., the charger 325 in FIG. 3). For example, the wearable device 202 may detect that the wearable device is connected to the charging cradle 201 based on the connector terminals 2020 being connected/contacted with the connector pins 230. The wearable device 202 may receive power from the connector terminals 2020, may convert the power into a charging current corresponding to the battery voltage, and may supply the charging current to the battery.

In operation 630, the wearable device 202 may determine whether a specific state related to battery charge-blocking, for example, at least one of a fully charged state, a coupling request signal, a firmware update signal, a TWS communication request signal, or a battery heat state, is recognized.

For example, the wearable device 202 may recognize a specific state related to charge-blocking based on the data/information transmitted from a communication circuit (e.g., the communication circuit 328 of FIG. 3), an input device (e.g., the input device 326 of FIG. 3), or a sensor (e.g., the sensor 327 of FIG. 3) (e.g., at least one of a temperature detection sensor, a gesture sensor, a voice recognition sensor, a magnetic pattern recognition sensor, a touch sensor, or a force sensor).

For example, in a case where the wearable device 202 receives a firmware update signal from an external electronic device (e.g., a smart phone) through a communication circuit, the wearable device 202 may recognize a specific state related to the firmware update signal.

In operation 640, in a case where a specific state related to battery charge-blocking is recognized (YES in operation 630), the wearable device 202 may turn off the charger connected to the connector terminals 2020 (e.g., the charger 325 of FIG. 3) to stop charging the battery.

For example, the wearable device 202 may turn off a power switch (e.g., the power switch 325-1 in FIG. 3) within the charger to turn off the charger. As the power switch is turned off, the electrical path configured to connect the charger and the battery may be cut off, thereby blocking battery charging.

In a case where the charger 325 is turned off, the charging current flowing to the connector terminals 2020 may fall to or below a predefined threshold because battery charging is blocked. While the battery of the wearable device 202 is charged, in a case where the charging cradle 201 detects a change in the charging current flowing to the connector pins 230 connected to the connector terminals 2020 falling to or below a predefined threshold, the charging cradle may recognize that a charge-blocking state has occurred in the wearable device 202.

In a case where a specific state related to battery charge-blocking is not recognized (NO in operation 630), the wearable device 202 may return to operation 620 and maintain the operation of charging the battery by using the power transmitted from the charging cradle 201.

In operation 650, the wearable device 202 may stand by in data communication mode. For example, when the wearable device 202 recognizes a specific condition related to battery charge-blocking, the wearable device may switch the UART port of the processor (e.g., the second processor 322 in FIG. 3) to the on state and wait in data communication mode. According to one or more embodiments, operation 650 may be omitted.

In operation 660, the wearable device 202 may perform data communication with the charging cradle through a transmission line connected to the connector terminals 2020 and the processor.

For example, the wearable device 202 may transmit data to the charging cradle 201 by using a method that causes the current of the connector terminals 2020 to have a current change corresponding to predefined bit information, or may obtain data transmitted from the charging cradle 201 by extracting predefined bit information from a current change.

For example, in a case where bit information defining a state information request is received from the charging cradle 201, the wearable device 202 may control the current change to include bit information defining a firmware update state to transmit the state information to the charging cradle 201.

A method of operating an electronic device (e.g., the charging cradle 201) according to one or more embodiments may include outputting power to charge a battery (e.g., the battery 321 of FIG. 3) of a wearable device 202 to the wearable device 202 through a first path (e.g., 3001 of FIG. 3) connected to a power supply (e.g., the power supply 311 of FIG. 3) of the electronic device (e.g., the charging cradle 201) and connector pins 230, based on that connector terminals 2020 of the wearable device 202 are in contact with the connector pins 230 of the electronic device (e.g., the charging cradle 201). A method of operating an electronic device (e.g., the charging cradle 201) according to one or more embodiments may include monitoring the charging current transmitted through the connector pins 230. A method of operating an electronic device (e.g., the charging cradle 201) according to one or more embodiments may include controlling a switch (e.g., the switch 315 in FIG. 3) disposed between a power supply and the connector pins to connect the connector pins 230 to the processor (e.g., the first processor 312 of FIG. 3) of the electronic device (e.g., the charging cradle 201) through the second path (3002 of FIG. 3) in a case where the monitored charging current changes to or below a configured threshold. A method of operating an electronic device (e.g., the charging cradle 201) according to one or more embodiments may include communicating of data with the wearable device 202 through the second path connected to the processor and the connector pins 230.

An operation of the communicating of the data with the wearable device 202 according to one or more embodiments may include requesting state information of the wearable device 202 from the wearable device 202, receiving the state information of the wearable device 202 from the wearable device 202, and performing a predefined function in response to the received state of the wearable device 202.

The operation of receiving state information of the wearable device 202 from the wearable device 202 according to one or more embodiments may further include displaying predefined information based on the state information of the wearable device 202.

A method of operating the wearable device 202 according to one or more embodiments may include charging the battery of the wearable device 202 (e.g., the battery 321 of FIG. 3) according to power supplied from the electronic device (e.g. the charging cradle 201) based on that the connector terminals 2020 of the wearable device 202 are in contact and connected with the connector pins 230 of the electronic device (e.g., the charging cradle 201). A method of operating the wearable device 202 according to one or more embodiments may include blocking charging of the battery by turning off a charger (e.g., the charger 325 of FIG. 3) connected to the battery, based on recognition of at least one of a fully charged state, a coupling request state, a software update state, a true wireless stereo (TWS) communication state, or a battery heat state, in relation to battery charge-blocking while the battery is charged.

A method of operating the wearable device 202 according to one or more embodiments may further include transmitting information or data related to the recognized state to the electronic device (e.g., the charging cradle 201) through a path connected to the processor of the wearable device 202 and the connector terminals, after blocking the battery charging.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
connector pins comprising a first pin and a second pin configured to transmit power or a communication signal;
a power supply;
a current detection sensor configured to detect charging current transmitted through the first pin;
at least one processor comprising processing circuitry;
a switch configured to connect one of the power supply and the at least one processor to the first pin; and
memory configured to store instructions,
wherein the instructions, when executed by the at least one processor individually or collectively, cause the electronic device to:
based on connector terminals of a wearable device being connected to the connector pins, transmit the power to the wearable device through a first path connected to the first pin and the power supply;
monitor the charging current of the first pin based on a measurement value provided by the current detection sensor;
based on the charging current changing to be at or below a threshold, control the switch to connect the at least one processor to the first pin; and
communicate data with the wearable device through a second path connected to the at least one processor and the first pin.

2. The electronic device of claim 1, wherein the first pin is configured to supply a first potential voltage and current, the second pin is configured to transmit a second potential voltage and current, and the first potential voltage is higher than the second potential voltage.

3. The electronic device of claim 1, wherein the instructions, when executed by the at least one processor individually or collectively, further cause the electronic device to, as operations to communicate the data with the wearable device through the second path:
request state information of the wearable device from the wearable device;
receive the state information of the wearable device from the wearable device; and
perform a function based on the state information of the wearable device.

4. The electronic device of claim 3, wherein the state information of the wearable device comprises at least one of a fully charged state, a coupling request state, a software update state, a true wireless stereo (TWS) communication state, or a battery heat state.

5. The electronic device of claim 1, further comprising:
a display,
wherein the instructions, when executed by the at least one processor individually or collectively, further cause the electronic device to display, via the display, information related to a charging state or an operating state of the electronic device, or a charging state or an operating state of the wearable device.

6. The electronic device of claim 1, wherein the current detection sensor is inside the power supply or on the first path, and
wherein the current detection sensor is further configured to sense current at two ends of a sensing resistor and transmit a value obtained by comparing current at the two ends of the sensing resistor to the at least one processor.

7. The electronic device of claim 1, wherein the current detection sensor is on a path configured to connect the second pin and a ground, and
wherein the current detection sensor is further configured to sense current at two ends of a sensing resistor and transmit a value obtained by comparing current at the two ends of the sensing resistor to the at least one processor.

8. The electronic device of claim 1, wherein the power supply comprises at least one of an external power source or a battery.

9. A wearable device comprising:
connector terminals comprising a first terminal and a second terminal;
a charger connected to a transmission line of the first terminal;
a battery connected to the charger;
at least one processor connected to the first terminal via the transmission line; and
memory comprising instructions,
wherein the instructions, when executed by the at least one processor individually or collectively, cause the wearable device to:
charge the battery using power transmitted from an electronic device through the connector terminals based on being connected to a connector pin of the electronic device configured to supply the power through the connector terminals;
identify at least one of a fully charged state, a coupling request state, a software update state, a true wireless stereo (TWS) communication state, or a battery heat state, as an identified state; and
block a connection between the charger and the connector terminals based on identifying the identified state while the battery is charged.

10. The wearable device of claim 9, wherein the charger further comprises a power switch, and
wherein the instructions the wearable device to:
turn off the power switch to block the connection between the charger and the connector terminals; and
transmit and receive data through the transmission line.

11. The wearable device of claim 9, further comprising:
at least one of an input device, a gesture sensor, a voice recognition sensor, a magnetic pattern recognition sensor, a touch sensor, or a force sensor,
wherein the instructions, when executed by the at least one processor individually or collectively, further cause the wearable device to:
detect a user input requesting coupling based on at least one of the input device, the gesture sensor, the voice recognition sensor, the magnetic pattern recognition sensor, the touch sensor, or the force sensor; and
block the connection between the charger and the connector terminals based on identifying the coupling request state from the user input.

12. The wearable device of claim 9, further comprising:
a communication circuit,
wherein the instructions further cause the wearable device to:
connect to an external electronic device through short-range wireless communication using the communication circuit; and
identify that the software update state or the TWS communication state occurs based on data received from the external electronic device through the communication circuit.

13. The wearable device of claim 9, further comprising:
a temperature detection sensor,
wherein the instructions, when executed by the at least one processor individually or collectively, further cause the wearable device to monitor the battery heat state through the temperature detection sensor to identify the battery heat state.

14. The wearable device of claim 11, wherein the instructions, when executed by the at least one processor individually or collectively, further cause the wearable device to transmit information or data related to the identified state to the electronic device through the transmission line.

15. A method for operating an electronic device, the method comprising:
based on connector terminals of a wearable device contacting a connector pin of the electronic device, outputting power for charging a battery of the wearable device to the wearable device through a first path connected to a power supply and the connector pin of the electronic device;
monitoring charging current transmitted through the connector pin;
based on the charging current changing to be at or below a threshold, controlling a switch between the power supply and the connector pin to connect the connector pin to at least one processor of the electronic device through a second path; and
communicating data with the wearable device through the second path.

16. The method of claim 15, wherein the connector pin comprises a first pin configured to supply a high potential voltage and current and a second pin configured to supply a low potential voltage and current, and
wherein the communicating the data with the wearable device comprises:
requesting state information of the wearable device from the wearable device;
receiving the state information of the wearable device from the wearable device; and
performing a function based on the state information of the wearable device.

17. The method of claim 16, wherein the state information of the wearable device comprises at least one of a fully charged state, a coupling request state, a software update state, a true wireless stereo (TWS) communication state, or a battery heat state.

18. The method of claim 16, wherein the receiving the state information of the wearable device from the wearable device further comprises displaying information based on the state information of the wearable device.

19. A method for operating a wearable device, the method comprising:
based on connector terminals of the wearable device contacting and connecting to a connector pin of an electronic device, charging a battery of the wearable device using power supplied from the electronic device;
identifying at least one of a fully charged state, a coupling request state, a software update state, a true wireless stereo (TWS) communication state, or a battery heat state related to charge-blocking of the battery, as an identified state; and
blocking charging of the battery by turning off a charger connected to the battery, based on identifying the identified state while the battery is charging.

20. The method of claim 19, further comprising, after the blocking charging of the battery, transmitting information or data related to the identified state to the electronic device through a path connected to at least one processor and the connector terminals of the wearable device.
